(19) United States
(12) Patent Application Publication
(10) Pub. No.: US 2014/0370664 A1
(43) Pub. Date: Dec. 18, 2014

(54) WORD LINE AND BIT LINE PROCESSING FOR CROSS-POINT MEMORIES

(71) Applicants: Kiran Pangal, Fremont, CA (US); Khaled Hasnat, San Jose, CA (US); Shafqat Ahmed, San Jose, CA (US)

(72) Inventors: Kiran Pangal, Fremont, CA (US); Khaled Hasnat, San Jose, CA (US); Shafqat Ahmed, San Jose, CA (US)

(21) Appl. No.: 13/917,068

(22) Filed: Jun. 13, 2013

(51) Int. Cl. H01L 27/105

(52) U.S. Cl. CPC H01L 27/1052
USPC 438/128

(57) ABSTRACT

Techniques for fabricating cross-point memory devices are disclosed in which word line (WL) and/or bit line (BL) processing is separate from cross-point memory memory-material processing, thereby providing an advantageous increase in thickness of the WL and/or BL metal that avoids an increase in the WL and BL resistances as feature sizes for cross-point memories scale smaller.

### TECHNICAL FIELD

Embodiments of systems and techniques described herein relate to memory devices. More particularly, embodiments of techniques for forming a cross-point memory device that can be, but not limited to, part of a solid-state memory array or a solid-state drive.

### BACKGROUND

The resistivity of the word line (WL) and bit line (BL) metal for cross-point memories correspondingly increases as feature sizes for cross-point memories scale smaller, which causes a loss of the read-window budget and an inability to provide sufficient current for cell operation.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 depicts a side cross-sectional view of a portion of an exemplary embodiment of a conventionally formed cross-point memory;

FIG. 2 depicts a side cross-sectional view of a portion of an exemplary embodiment of a cross-point memory formed according to the subject matter disclosed herein; and

FIG. 3 depicts a flow diagram of an exemplary embodiment of a method for processing word line (WL) and/or bit line (BL) metal independently from cross-point memory memory-material processing according to the subject matter disclosed herein.

It will be appreciated that for simplicity and/or clarity of illustration, elements depicted in the figures have not necessarily been drawn to scale. For example, the dimensions of some of the elements may be exaggerated relative to other elements for clarity. The scaling of the figures does not represent precise dimensions and/or dimensional ratios of the various elements depicted herein. Further, if considered appropriate, reference numerals have been repeated among the figures to indicate corresponding and/or analogous elements.

### DESCRIPTION OF THE EMBODIMENTS

Embodiments of techniques described herein relate to memory devices and, more particularly, embodiments of techniques for forming cross-point memory devices, such as, but not limited to, memory devices for solid-state memory arrays or solid-state drives. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments. Additionally, the word “exemplary” is used herein to mean “serving as an example, instance, or illustration.” Any embodiment described herein as “exemplary” is not to be construed as necessarily preferred or advantageous over other embodiments.

Various operations may be described as multiple discrete operations in turn and in a manner that is most helpful in understanding the claimed subject matter. The order of description, however, should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

Embodiments of the subject matter disclosed herein provide techniques for processing word line and/or bit line metal independently from cross-point memory memory-material processing, thereby providing an increase in thickness of the word line (WL) and/or bit line (BL) metal as feature sizes for cross-point memories scale smaller. That is, embodiments of the subject matter disclosed herein provide a technique for preventing increases in WL and/or BL resistances as the cross-point memory feature sizes become smaller. Moreover, embodiments of the techniques disclosed herein can be used to fabricate cross-point memories that comprise part of a multi-die (or multi-chip or multi-device) that can be, but is not limited to, a solid-state memory array or a solid-state drive.

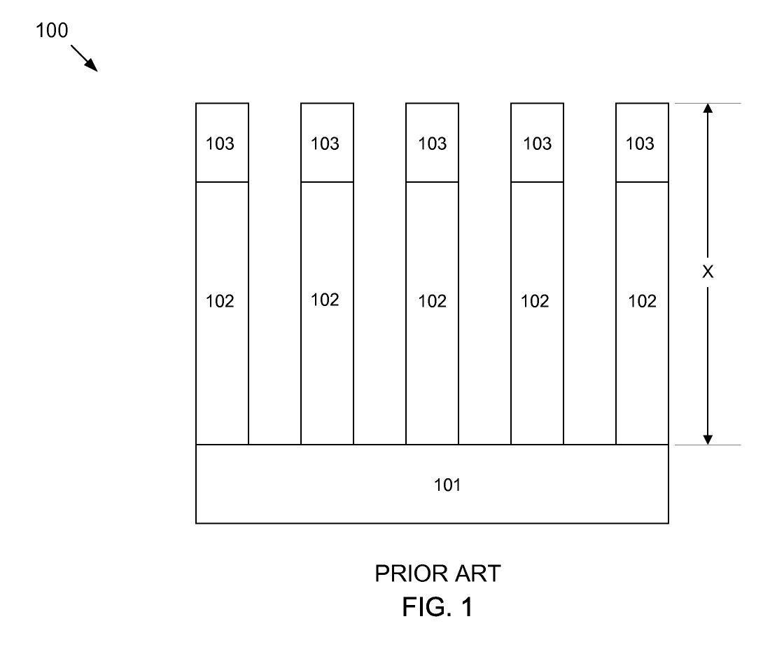

FIG. 1 depicts a side cross-sectional view of a portion of an exemplary embodiment of a conventionally formed cross-point memory 100. Memory 100 comprises word line (WL) metal 101, memory material 102 and bit line (BL) metal 103. In the exemplary embodiment shown in FIG. 1, WL metal 101 is formed on a substrate (not shown). Memory material 102 is formed on WL metal 101, and BL metal 103 is formed on memory material 102.

When memory 100 is conventionally formed, both the WL metal 101 and BL metal 103 etches also have to perform an etch for the memory material 102. WL metal 101 etch performs memory material 102 etch in one direction and BL metal 103 etch performs memory material 102 etch in the orthogonal direction. With the combination of these two etches, individual memory cells are formed at the intersection of the WL and BL. Therefore, both the WL 101 and BL 103 metals have to withstand the etch of memory material 102 in order to provide the total height X of memory material 102 and WL/BL metals. Typical aspect ratios for conventionally formed cross-point memories range from about 10:1 to about 12:1. As cross-point memory dimensions are scaled smaller, one approach for compensating for the increase in the resistances of the BL/WL metal is to increase the thicknesses of the WL/BL metal. Using the conventional fabrication techniques to increase the thicknesses of the WL and BL metal, however, causes the overall aspect ratio of the total memory to increase, which has a tendency to limit the thicknesses of the WL/BL metals, thereby resulting in a net higher WL/BL resistance for a given array size. Additionally, an increase in the WL/BL resistances tends to cause an increased error rate, resulting in a device having poor reliability. Thus, to conventionally compensate for higher BL/WL resistances caused by conventional cross-point memory fabrication techniques, memory cells are arranged in smaller array tiles, which results in a larger die size for a given memory density.

Embodiments of the subject matter disclosed herein reduce WL/BL resistances as cross-point memory dimensions are scaled smaller by providing a technique in which WL/BL is processed independently from memory-material processing. According to the subject matter disclosed herein, additional lithography and BL/WL metal etch processing are included in cross-point memory fabrication to reduce WL/BL resistances as cross-point memory dimensions are scaled smaller. The separate metal deposition and etches do not adversely impact the aspect ratio of a memory cell. For example, the aspect ratio for a memory cell formed using embodiments of the subject matter disclosed herein ranges from about 6:1 to about 8:1.

Moreover, because the WL/BL metal does not undergo memory etch processing, the metal thickness can be independently increased to provide a lower metal resistivity as cross-point memory features scale smaller, and the decrease in metal resistivity significantly increases the overall memory operating window, thereby improving product performance and device reliability. For example, for a 20 nm cross-point memory device, embodiments of the subject matter disclosed herein reduces the overall array resistance by about 30%, and provides about 100 mV of window-budget margin and about a 20% increase in write-current capability.

Further, embodiments of the subject matter disclosed herein provide a technique for independent etching of the memory material processing that separately optimizes WL and BL resistances and capacitances to mitigate cell disturb. For example, for a 20 nm cross-point memory device, the WL capacitance can be reduced by fabricating a thinner WL metal stack while simultaneously reducing the BL resistance (i.e., a thicker BL metal) to keep the overall WL/BL resistance constant. Moreover, the thinner WL metal stack reduces the RC-dependent delay.

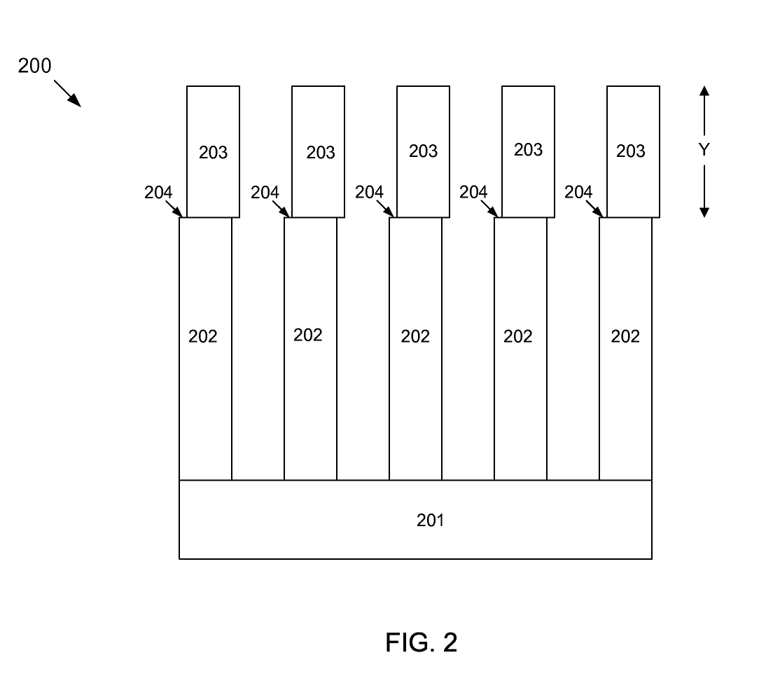

FIG. 2 depicts a side cross-sectional view of a portion of an exemplary embodiment of a cross-point memory 200 formed according to the subject matter disclosed herein. In one exemplary embodiment, cross-point memory 200 comprises part of a multi-die (or multi-chip or multi-device) configuration, such as, but not limited to, a solid-state memory array or a solid-state drive. Memory 200 comprises word line (WL) metal 201, memory material 202 and bit line (BL) metal 203. In the exemplary embodiment shown in FIG. 2, WL metal 201 is formed on a substrate (not shown). Suitable materials for WL metal 201 include, but are not limited to, tungsten, copper and aluminum. Memory material 202 is formed on WL metal 201. WL metal 201 and memory material 202 are then etched along the WL direction. A separate step is then used to etch the memory material 202 in the BL direction. BL metal 203 is formed on etched memory material 202 and then etched separately from the memory-material etching. Suitable materials for BL metal layer 203 include, but are not limited to, tungsten, copper and aluminum.

According to embodiments of the subject matter disclosed herein, BL metal 203 and memory material 202 are each etched in separate processing steps. The separate processing steps may cause a slight misalignment between the BL metal 203 and memory material 202, as indicated at 204. Separately etching BL metal 203 allows the BL metal thickness Y to be selectively increased to any desired thickness in contrast to conventional fabrication techniques for cross-point memories.

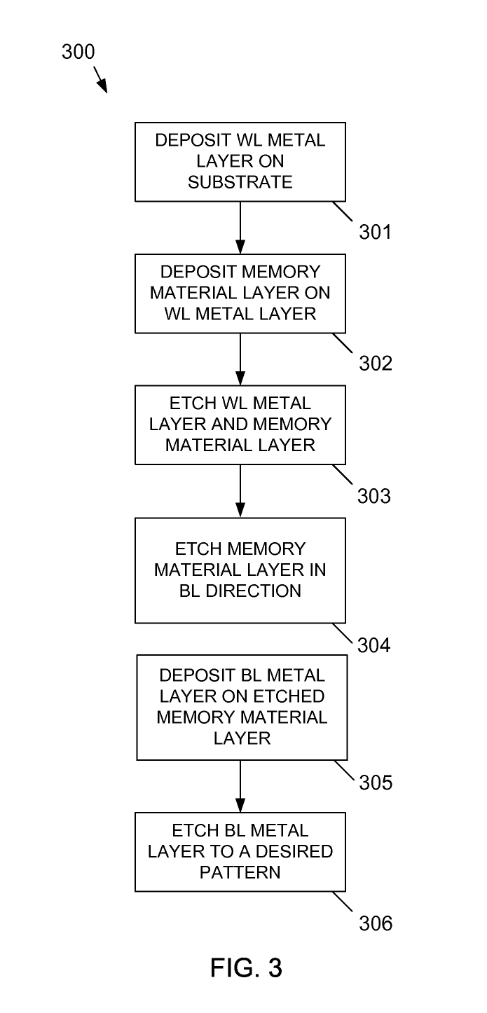

FIG. 3 depicts a flow diagram 300 of an exemplary embodiment of a method for processing word line (WL) and/or bit line (BL) metal independently from cross-point memory memory-material processing according to the subject matter disclosed herein. Reference should be made to FIG. 2 for a depiction of side cross-sectional view of a portion of an exemplary embodiment of a cross-point memory formed according to the subject matter disclosed herein. At 301, WL metal layer (i.e., WL metal 201) is deposited to a desired thickness on a substrate (not shown) in a well-known manner. At 302, memory material layer (i.e., memory material 202) is deposited on the WL metal layer using a well-known deposition technique. At 303, the WL metal layer and the memory material layer are etched to a desired pattern using a well-known dry-etch technique. At 304, the memory material is then etched along the BL direction. At 305 a BL metal layer (i.e., BL metal 203) is deposited to a desired thickness on the etched memory material using a well-known deposition technique. At 306, the BL metal layer is etched to a desired pattern using a well-known dry-etch technique. Etching the BL metal layer separately from the memory material layer permits the BL metal layer thickness Y (FIG. 2) to be selectively increased because the BL metal layer does not need to withstand the memory-material etch and is not part of the aspect ratio of the memory material as fabricated and etched. Moreover, etching the WL and/or BL metal layers separately from the memory-material etches does not add any additional etching constraints for the memory material. Although the Figures depict the word line metal as being formed directly on the substrate and the bit line metal being formed on the memory material, it should be understood that the bit line metal could alternatively be formed directly on the substrate and the word line metal be formed on the memory material.

These modifications can be made in light of the above detailed description. The terms used in the following claims should not be construed to limit the scope to the specific embodiments disclosed in the specification and the claims. Rather, the scope of the embodiments disclosed herein is to be determined by the following claims, which are to be construed in accordance with established doctrines of claim interpretation.

1. A method for forming a cross-point memory device, the method comprising:
forming a first metal layer on a substrate;
forming a memory-material layer on the first metal layer;
etching the memory-material layer to have a desired pattern and a desired aspect ratio;
forming a second metal layer to a desired thickness on the etched memory-material layer; and
etching the second metal layer to match the desired pattern of the etched memory-material layer, the etching of the second metal layer being separate from the etching of the memory-material layer.

2. The method according to claim 1, wherein etching the memory-material layer further comprises etching the first metal layer during the etching of the memory-material layer.

3. The method according to claim 1, wherein etching the memory-material layer etches the first metal layer to the desired pattern.

4. The method according to claim 1, wherein the first metal layer comprises a word line metal layer and the second metal layer comprises a bit line metal layer.

5. The method according to claim 1, wherein the first metal layer comprises a bit line metal layer and the second metal layer comprises a word line metal layer.

6. The method according to claim 1, wherein an aspect ratio of the etched memory-material layer comprises about 6:1 to about 8:1.

7. The method according to claim 1, wherein the cross-point memory device comprises part of a multi-die solid-state memory array or a multi-die solid-state drive.

8. The method according to claim 1, wherein the cross-point memory device comprises part of a solid-state memory array or a solid-state drive.

9. A method, comprising:
forming a first metal layer for a cross-point memory device to a first desired thickness on a substrate;
forming a memory-material layer on the first metal layer;
etching the memory-material layer to have a desired pattern and a desired aspect ratio;
forming a second metal layer to a second desired thickness on the etched memory-material layer, the first desired thickness of the first metal layer and the second desired thickness of the second metal layer being selected together to form a predetermined amount of resistance provided by the first and second metal layers; and
etching the second metal layer to match the desired pattern of the etched memory material, the etching of the second metal layer being separate from the etching of the memory-material layer.

10. The method according to claim 9, wherein etching the memory-material layer further comprises etching the first metal layer during the etching of the memory-material layer.

11. The method according to claim 9, wherein etching the memory material layer etches the first metal layer to the desired pattern.

12. The method according to claim 9, wherein the first metal layer comprises a word line metal layer and the second metal layer comprises a bit line metal layer.

13. The method according to claim 9, wherein the first metal layer comprises a bit line metal layer and the second metal layer comprises a word line metal layer.

14. The method according to claim 9, wherein the cross-point memory device comprises part of a multi-die solid-state memory array or a multi-die solid-state drive.

15. The method according to claim 9, wherein the cross-point memory device comprises part of a solid-state memory array or a solid-state drive.

16. A method for forming a cross-point memory device, the method comprising:
forming a memory-material layer on a word line metal layer;
etching the memory-material layer to have a desired pattern and a desired aspect ratio;
forming a bit line metal layer to a desired thickness on the etched memory-material layer; and
etching the bit line metal layer to match the desired pattern of the etched memory-material layer, the etching of the bit line metal layer being separate from the etching of the memory-material layer.

17. The method according to claim 16, wherein an aspect ratio of the etched memory-material layer comprises about 6:1 to about 8:1.

18. The method according to claim 16, wherein the cross-point memory device comprises part of a multi-die solid-state memory array or a multi-die solid-state drive.

19. The method according to claim 16, wherein the cross-point memory device comprises part of a solid-state memory array or a solid-state drive.

20. The method according to claim 16, wherein the desired thickness of the bit line metal layer being selected to form a predetermined amount of resistance provided by the bit line metal layer and the word line metal layer;
